(19) United States
(12) Patent Application Publication
(10) Pub. No.: US 2012/0111610 A1
(43) Pub. Date: May 10, 2012

(54) HEAT-RADIATING SUBSTRATE AND METHOD FOR MANUFACTURING THE SAME

(75) Inventors: Kwang Soo KIM, Gyunggi-do (KR); Sang Hyun SHIN, Gyunggi-do (KR); Jung Eun KANG, Gyunggi-do (KR); Chang Hyun LIM, Seoul (KR); Seog Moon CHOI, Seoul (KR); Sung Keun PARK, Gyunggi-do (KR)

(73) Assignee: SAMSUNG ELECTRO-MECHANICS CO., LTD., Gyunggi-do (KR)

(21) Appl. No.: 13/013,736

(22) Filed: Jan. 25, 2011

(30) Foreign Application Priority Data
Nov. 5, 2010 (KR) 10-2010-0109984

(51) Int. Cl. H05K 1/02; C23C 28/00

(52) U.S. Cl. 174/252; 205/199

(57) ABSTRACT

Disclosed herein are a heat-radiating substrate and a method for manufacturing the same. The heat-radiating substrate includes: an anodized substrate having an anodized film formed over a metal substrate; a circuit pattern formed on one surface of the anodized substrate; and a metal layer formed on the other surface of the anodized substrate. The metal layer formed on the other surface of the anodized substrate has the same area as that of the circuit pattern formed on one surface thereof, and is formed within an edge of the anodized substrate. The metal layer is added, making it possible to minimize a warpage problem of the substrate. In addition, a heat radiating plate is in direct contact with the anodized substrate, thereby making it possible to solve a performance deterioration problem of the heat-radiating substrate and a heat generating element and improve a heat-radiating performance.

### CROSS REFERENCE TO RELATED APPLICATION

This application claims the benefit of Korean Patent Application No. 10-2010-0109984, filed on Nov. 5, 2010, entitled “Heat-Radiating Substrate and Method for Manufacturing the Same”, which is hereby incorporated by reference in its entirety into this application.

### BACKGROUND OF THE INVENTION

1. Technical Field

The present invention relates to a heat-radiating substrate and a method for manufacturing the same.

2. Description of the Related Art

Recently, as electronic components are widely used in various fields, heat generation due to high-integration and high-capacity components has caused performance deterioration of a product. In order to solve this problem, research into a high-efficiency heat-radiating substrate using a metal material having good thermal conductivity has continuously been conducted.

A structure of a heat-radiating substrate according to the prior art will be described below.

First, anodized films are formed on one surface or the entire surface of aluminum by applying an anodizing method to the aluminum.

Then, a plating layer is formed on the anodized film formed on an upper surface of the aluminum and is processed to form a circuit pattern. Thereafter, the circuit pattern is electrically connected to a heat generating element and the anodized film formed on a lower surface of the aluminum (or a lower surface of aluminum itself in the case of forming the anodized film only on the upper surface of the aluminum) is connected to a heat-radiating plate, such that heat generated from the heat generating element is radiated to the outside through the aluminum and the heat-radiating plate. Accordingly, the heat generating element formed on the heat-radiating substrate may effectively radiate high heat. Therefore, a problem that the performance of the heat generating element is deteriorated may be solved.

However, the heat-radiating substrate according to the prior art had a structure in which the circuit pattern is formed only on the upper surface of the substrate. Accordingly, warpage has been generated due to stress applied to the heat-radiating substrate. In addition, since the anodized film formed on the lower surface of the aluminum (or the lower surface of aluminum itself in the case of forming the anodized film only on the upper surface of the aluminum) is in direct contact with the heat-radiating plate, a corner breakage phenomenon in a repetitive processing process such as loading, transfer, carrying-out, and the like, of the substrate within a predetermined control environment may occur. Therefore, the performance of the heat-radiating substrate or the heat generating element has been deteriorated.

### SUMMARY OF THE INVENTION

The present invention has been made in an effort to provide a heat-radiating substrate capable of improving a warpage phenomenon of a heat-radiating substrate, improving performance deterioration problems such as a corner breakage phenomenon and improving thermal conductivity by additionally forming a metal layer on a lower surface of an anodized substrate and a method for manufacturing the same.

According to a preferred embodiment of the present invention, there is provided a heat-radiating substrate, including: an anodized substrate having an anodized film formed over a metal substrate; a circuit pattern formed on one surface of the anodized substrate; and a metal layer formed on the other surface of the anodized substrate.

The metal layer formed on the other surface of the anodized substrate may have the same area as that of the circuit pattern formed on one surface thereof.

A thickness of the metal layer may be 10 μm or more to 1 mm or less.

The metal layer may have a shape in which a plurality of bars are disposed in parallel with each other.

The metal layer may include an outermost metal layer formed in a rectangular shape by connecting four bars at an outermost portion inside an edge of the anodized substrate, N intermediate metal layers formed in rectangular shapes inside the outermost metal layer and having reduced-size rectangular shapes toward an inner center of the anodized substrate, and innermost metal layers formed inside the intermediate metal layer formed at an innermost portion of the N intermediate metal layers and having a plurality of bar shapes arranged in parallel with each other.

The metal layer may have a spiral shape.

The metal layer may be formed only within an edge on the other surface of the anodized substrate.

The metal substrate may be made of aluminum and the anodized film may be made of alumina.

The metal layer may be made of copper.

The heat-radiating substrate may further include a seed layer between one surface of the anodized substrate and the circuit pattern or between the other side of the anodized substrate and the metal layer.

The circuit pattern formed on one surface of the anodized substrate may be connected to a heat generating element and the metal layer formed on the other surface thereof may be connected to a heat-radiating plate.

According to a preferred embodiment of the present invention, there is provided a method for manufacturing a heat-radiating substrate, including: (A) forming an anodized film over a metal substrate to prepare an anodized substrate; (B) forming a plating layer on one surface of the anodized substrate and forming a metal layer on the other surface thereof through a plating process; and (C) patterning the plating layer to form a circuit pattern.

The method for manufacturing a heat-radiating substrate may further include, after step (A), (A′) forming a seed layer using an electroless plating process or a sputtering process.

The plating layer and the metal layer may be simultaneously formed.

The method for manufacturing a heat-radiating substrate may further include, after step (B), removing an edge of the metal layer so that the metal layer is formed only within an edge on the other surface of the anodized substrate.

The method for manufacturing a heat-radiating substrate may further include patterning the metal layer so that the metal layer formed on the other surface of the anodized substrate has the same area as that of the circuit pattern formed on one surface of the anodized substrate.

The metal substrate may be made of aluminum and the anodized film may be made of alumina.

The metal layer may be made of copper.

### BRIEF DESCRIPTION OF THE DRAWINGS

FIG. 1 is a cross-sectional view of a heat-radiating substrate according to a preferred embodiment of the present invention;

FIGS. 2 to 8 are process cross-sectional views sequentially showing a method for manufacturing a heat-radiating substrate according to a preferred embodiment of the present invention;

FIGS. 9 and 10 are cross sectional views showing a structure in which a heat-generating element is mounted on the heat-radiating substrate show in FIG. 1;

FIG. 11 is a graph showing a change in thermal conductivity according to a thickness of a metal layer (Cu); and

FIGS. 12 to 14 are bottom views of the heat-radiating substrate shown in FIG. 1.

### DESCRIPTION OF THE PREFERRED EMBODIMENTS

Features and advantages of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Various objects, advantages and features of the invention will become apparent from the following description of embodiments with reference to the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

Structure of Heat-Radiating Substrate

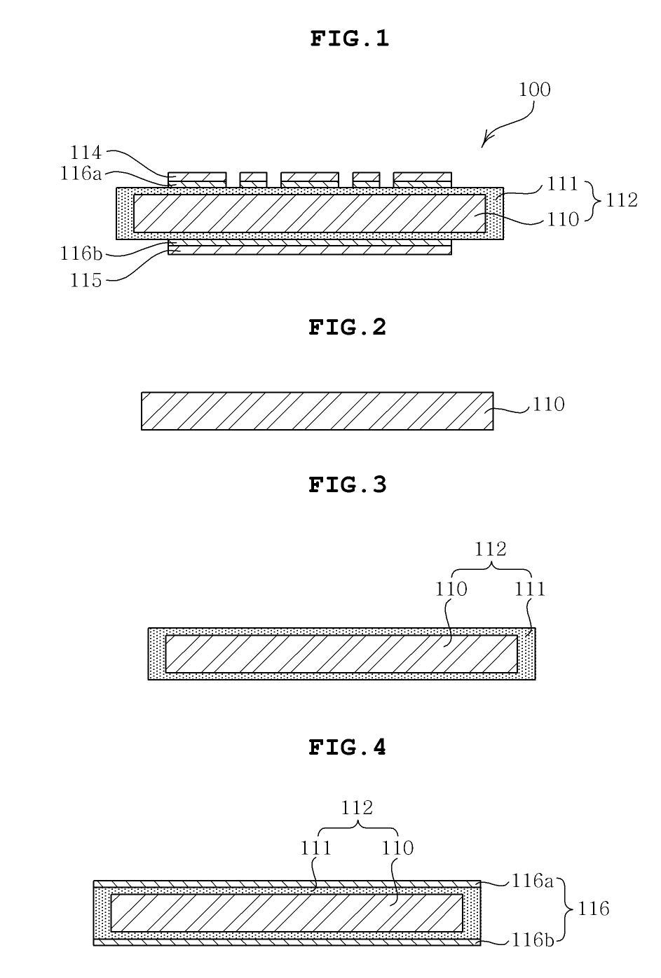

FIG. 1 is a cross-sectional view of a heat-radiating substrate 100 according to a preferred embodiment of the present invention.

As shown in FIG. 1, a heat-radiating substrate 100 according to a preferred embodiment of the present invention is configured to include an anodized substrate 112 having an anodized film 111 formed over a metal substrate 110, a seed layer 116 formed on the anodized substrate 112, a circuit pattern 114 formed on a first seed layer 116a and a metal layer 115 formed on a second seed layer 116b.

The metal substrate 110, which is a basic member of the heat-radiating substrate 100, is a member radiating heat generated from a heat generating element 130 in the air. Since the metal substrate 110 is made of a metal, it has an excellent heat-radiating effect due to high thermal conductivity. In addition, the metal substrate 110 has strength stronger than a substrate made of a general resin layer, such that resistance to warpage is large. Herein, the metal substrate 110 is preferably made of aluminum (Al), without being necessarily limited thereto, and may be made of manganese (Mn), zinc (Zn), titanium (Ti), hafnium (Hf), tantalum (Ta), or niobium (Nb).

The anodized substrate 112 is formed by forming the anodized film 111 on the metal substrate 110. Herein, the anodized film 111, which is an insulating layer formed over the metal substrate 110, insulates the metal substrate from the metal substrate so that the circuit pattern 114 and the metal substrate 110 are not electrically short-circuited. When the metal substrate 110 is made of an aluminum (Al) metal, the anodized film 111 is made of alumina (Al₂O₃) formed by oxidizing the aluminum metal. When the metal substrate 110 is made of the aluminum and the anodized film 111 is made of alumina, the heat-radiating substrate 100 has an excellent heat-radiating effect. Herein, the anodized film 111 may be formed at a thickness of several μm to several hundred μm according to usage.

The seed layer 116, which is a thin metal film formed on the anodized film 111 using an electroless plating process or a sputtering process, serves as a lead line in subsequently forming a plating layer 113 and the metal layer 115 on the anodized film 111. In order to make a structure of the substrate symmetrical in up and down directions, the seed layer 116 is formed on one surface and the other surface of the anodized substrate 112 at an equal thickness. However, the seed layer may be omitted according to a plating method of the plating layer.

The circuit pattern 114 is formed by patterning the plating layer 113 formed on one surface of the anodized film 111 (the first seed layer 116a formed on one surface of the anodized film 111) using a wet plating process or a dry sputtering process.

Herein, the circuit pattern 114 is electrically connected to the heat generating element 130, other components or other wirings.

The metal layer 115 is formed on the other surface of the anodized film 111 (the second seed layer 116b formed on the other surface of the anodized film 111) using a wet plating process or a dry sputtering process.

Herein, the metal layer 115 is formed only within an edge on the other surface of the anodized substrate 112, such that a corner portion of the anodized substrate 112 is not in direct contact with a heat-radiating plate 140.

In addition, in order to minimize a warpage phenomenon of the substrate, the metal layer 150, preferably, has the same area as that of the circuit pattern 114. The metal layer formed on the other surface of the anodized substrate 112 may be patterned to have the same area as that of the circuit pattern 114 and may be in a plate-shaped structure having the same area as that of the circuit pattern 114. Although the metal layer 115 according to the present embodiment is patterned to have the same area as that of the circuit pattern 114, it is only a configuration added in order to prevent warpage of the substrate and improve a heat-radiating effect and is different from a normal double-sided anodized substrate in that it is not used as a circuit pattern.

Meanwhile, when the same area is not possible due to characteristics of the substrate, a thickness of the metal layer 115 may be adjusted and selected. However, in consideration of the substrate thinning, the thickness of the metal layer 115 is preferably selected in the limited range of 10 μm to 1 mm. Meanwhile, an experiment has demonstrated that when the metal layer 115 is made of a copper layer, as the thickness of the copper layer is increased, thermal conductivity of the anodized substrate is linearly increased. For example, in the case of forming the anodized film 111 having a thickness of 25 μm on both surfaces of the aluminum substrate having a thickness of 4 mm to prepare the anodized substrate 112 and forming the circuit pattern having a thickness of 200 μm on the first seed layer 116a on one surface of the anodized substrate 112, as the thickness of the copper layer formed on the second seed layer 116b is increased up to 400 μm, thermal conductivity of the anodized substrate 112 was increased up to 6% (refer to FIG. 11).

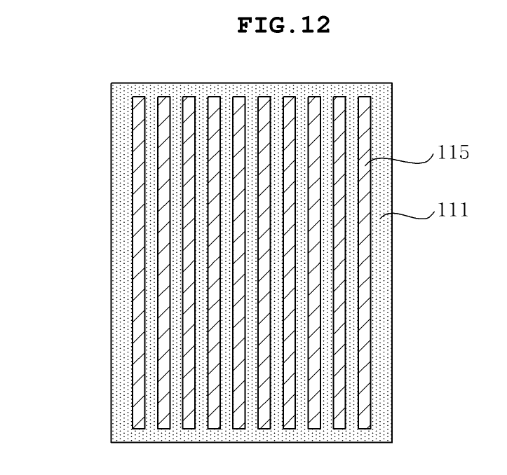

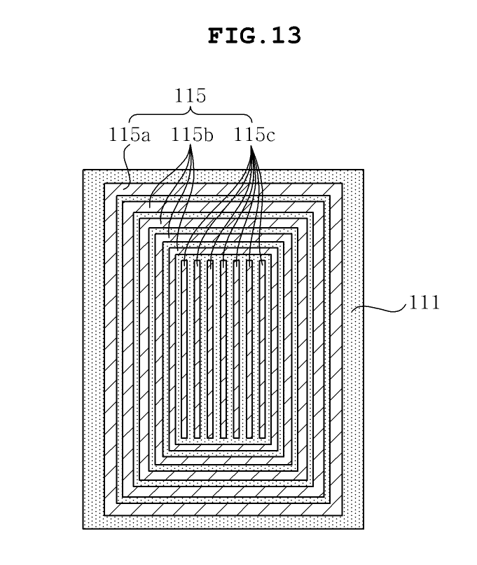

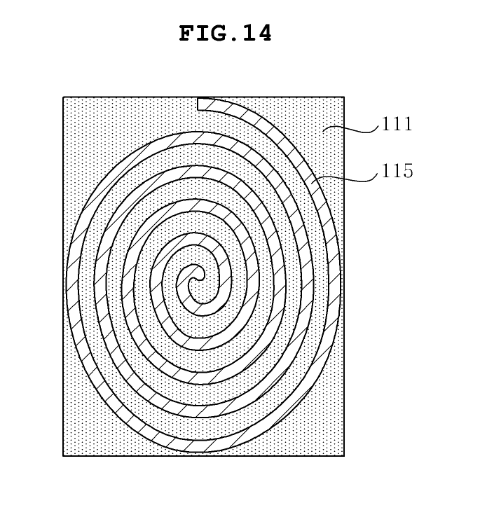

In addition, in order to maximize efficiency of thermal conductivity, the metal layer 115 may have a fin shape (FIG. 12), a box-fin shape (FIG. 13) or a spiral shape (FIG. 14), as shown in FIGS. 12 to 14. The fin shape indicates a shape in which a plurality of bars are protruded from the other surface of the anodized substrate 112 (refer to FIG. 1) and are arranged to be in parallel with each other. That is, the fin shape means a shape in which N bars formed to be extended from one side of the edge of the anodized substrate 112 to the other side thereof are arranged to be in parallel with each other to be spaced by predetermined intervals. In addition, the box-fin shape is configured to include an outermost metal layer 115a formed in a rectangular shape by connecting four bars at an outermost portion inside the edge of the anodized substrate 112, N intermediate metal layers 115b formed in rectangular shapes inside the outermost metal layer 115a and having reduced-size rectangular shapes toward an inner center of the anodized substrate 112 and innermost metal layers 115c formed inside the intermediate metal layer 115b formed at an innermost portion of the N intermediate metal layers 115b and having a plurality of bar shapes arranged in parallel with each other. That is, the box-fin shape means a structure in which the outermost metal layer 115a and the intermediate metal layers 115b having increasingly reduced sizes in a direction from the outermost portion inside the edge of the anodized substrate 112 to the center of the anodized substrate 112 are formed and a plurality of innermost metal layers 115c in a bar shape disposed in parallel with any one of four bars configuring the intermediate metal layer 115b formed in the innermost portion is formed inside the intermediate metal layer 115b formed in the innermost portion. In addition, the spiral shape means a vortex shape in which a bar is protruded from the anodized substrate 112 and is formed in the edge of the anodized substrate 112.

Meanwhile, the metal layer 115 may be made of copper. The copper has relatively easy processing characteristics to easily implement various shapes and may also have an appropriate strength to suppress the generation of the warpage of the anodized substrate. For example, in the case of manufacturing the double sided anodized substrate 112 using the copper as the metal layer 115, when comparing a warpage phenomenon in an existing single-sided anodized substrate with a warpage phenomenon of the double-sided anodized substrate 112 using an aluminum substrate having a thickness of 4 mm, it can be confirmed that the degree of the warpage was reduced from 72 μm to 52 μm, that is, by 28%.

In addition, since copper is relatively excellent in thermal conductivity and electric conductivity as compared to other metals, it has improved heat-radiating characteristics.

In addition, since copper is relatively cheap in cost, it is possible to reduce manufacturing cost of the heat-radiating substrate.

Meanwhile, the plating layer 113 and the metal layer 115 may be simultaneously formed.

Method for Manufacturing Heat-Radiating Substrate

FIGS. 2 to 8 are process cross-sectional views for explaining a method for manufacturing a heat-radiating substrate 100 according to a preferred embodiment of the present invention. Hereinafter, a method for manufacturing a heat-radiating substrate 100 according to a preferred embodiment of the present invention will be described with reference to FIGS. 2 to 8.

First, as shown in FIG. 2, a metal substrate 110 is prepared.

At this time, the metal substrate 110 is processed in a thickness and a width to be manufactured. The metal substrate 110 may be made of a metal having excellent thermal conductivity. For example, the metal substrate is preferably made of aluminum (Al), without being necessarily limited thereto, and may be made of manganese (Mn), zinc (Zn), titanium (Ti), hafnium (Hf), tantalum (Ta), or niobium (Nb).

Then, as shown in FIG. 3, an anodized film 111 is formed over the metal substrate 110 to manufacture an anodized substrate 112. Herein, the anodized film 111, which is an insulating layer, insulates the metal substrate from the circuit pattern so that the circuit pattern 114 and the metal substrate 110 are not electrically short-circuited.

A process for forming the anodized film will be described in detail. The metal substrate 110 is connected to a positive electrode of a DC power supply and is immersed in an acid solution (electrolyte solution), thereby making it possible to form an insulating layer configured of the anodized film 111 on the surface of the metal substrate 110. For example, when the metal substrate 110 is made of aluminum, the surface of the metal substrate 110 reacts with the electrolyte solution to form aluminum ions (Al³⁺) on the interface thereof. Current density is concentrated on the surface of the metal substrate 110 by the voltage applied to the metal substrate 110 to locally generate heat, such that more aluminum ions are formed due to the heat. As a result, a plurality of grooves are formed in the surface of the metal substrate 110 and oxygen ions (O²⁻) move to the grooves by the force of an electric field to react with the electrolytic aluminum ions, thereby making it possible to form the anodized film 111 made of an alumina layer.

Herein, since the anodized film 111 has excellent thermal conductivity as compared to other insulating members, although the anodized film 111 is formed over the metal substrate 110, heat exchange may be smoothly performed between the metal substrate 110 and the heat-radiating plate 140. In addition, when the metal substrate 110 is made of an aluminum (Al) metal, the insulating layer may be made of alumina formed by anodizing the aluminum (Al) metal. In this case, heat exchange rate may be further raised.

Thereafter, as shown in FIG. 4, the seed layer 116 is formed on one surface or the other surface of the anodized substrate 112. The seed layer 116 is a thin metal film formed on the anodized film 111 using an electroless plating process or a sputtering process. Generally, the electroless plating process is performed as a pre-treatment process for performing an electro plating process. At this time, the seed layer 116 may be formed at a thickness appropriate for performing the electro plating. Meanwhile, the sputtering process, which is a scheme of spraying metal particles onto a target surface to deposit a thin film made of a metal, may form a thin film made of a material such as gold, silver, copper, and the like.

Herein, in order to minimize a warpage phenomenon by making a structure of the substrate symmetrical in up and down directions, the seed layer 116 is formed on both surfaces of the anodized film 111 at an equal thickness. However, a process for forming the seed layer 116 may be omitted according to a plating method of the plating layer.

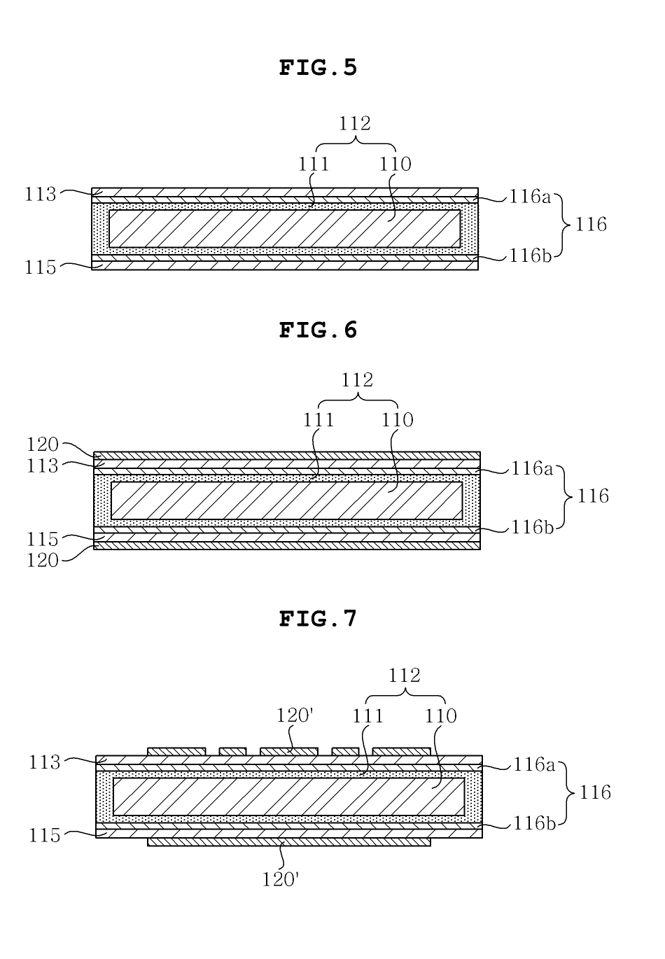

Then, as shown in FIG. 5, a plating layer 113 and a metal layer 115 are formed on one surface or the other surface of the anodized substrate 112 (or a first seed layer 116a or a second seed layer 116b formed on the anodized film 111) through a dry sputtering (or wet plating) process.

Herein, the plating layer 113 is subjected to photosensitization, development and etching processes described below and then forms a circuit pattern 114 (including a pad). In addition, edges of the metal layer 115 may be removed through etching. The metal layer 115 may be made of a metal having excellent thermal conductivity and strength enough to endure external force applied to the heat-radiating substrate 100, and preferably, copper. In addition, the plating layer 113 and the metal layer 115 may be simultaneously formed.

Next, as shown in FIGS. 6 and 7, an etching resist 120 is applied on the plating layer 113 and the metal layer 115 and etching resist patterning is performed.

First, the etching resist 120 applied on the plating layer 113 is subjected to a predetermined process to be patterned into an etching resist pattern 120′. Specifically, after applying a thy film, and the like, on the plating layer and the metal layer to form the etching resist 120, the etching resist 120 is irradiated with ultraviolet light in the state of being blocked with a mask. Thereafter, when applying developing solution to the etching resist 120, the portion cured by ultraviolet irradiation remains; however, the non-cured portion is removed to form the etching resist pattern 120′. At this time, a shape of the etching resist pattern 120′ is the same as that of the circuit pattern 114 to be later formed through the photosensitization, development and etching processes.

In addition, in order to remove the metal layer 115 formed at the edge of the anodized substrate 112, the etching resist 120 applied on the metal layer 115 is patterned so that the edge of the metal layer 115 is exposed. In addition, the etching resist 120 formed on the metal layer 115 is patterned so that the metal layer 115 has the same area as that of the circuit pattern 114, thereby forming the etching resist pattern 120′. A process for forming the etching resist pattern 120′ on the metal layer 115 is the same as that for forming the etching resist pattern 120′ in order to form the circuit pattern 114. At this time, the process for the forming the etching resist pattern 120′ on the plating layer 113 and the process for forming the etching resist pattern 120′ on the metal layer 115 may be simultaneously performed.

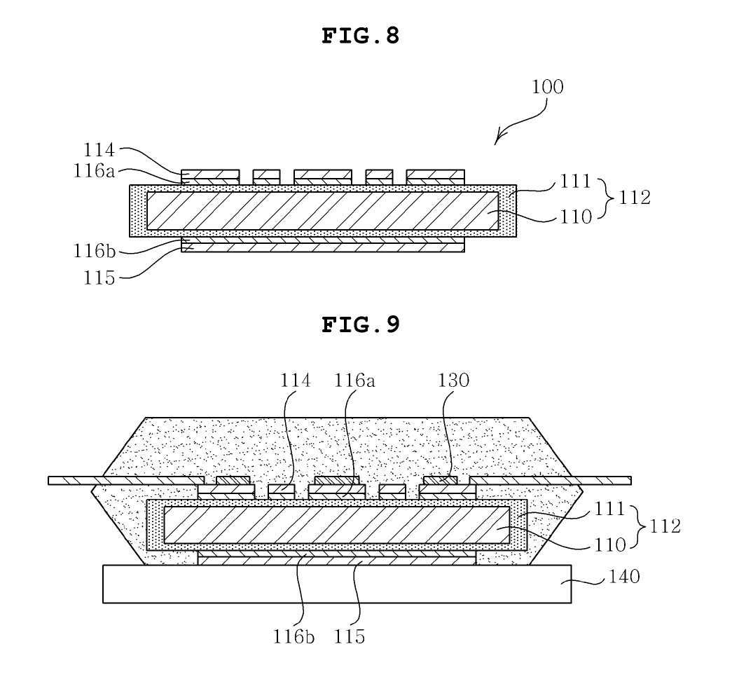

Finally, as shown in FIG. 8, the plating layer 113 and the first seed layer 116a are etched and the etching resist pattern 120′ is peeled off to form the circuit pattern 114. In addition, the metal layer 115 and the second seed layer 116b are etched and the etching resist pattern 120′ is peeled off.

Herein, the edge of the metal layer 115 is removed, such that the metal layer 115 exists only within the edge on the other surface of the anodized substrate 112. The area of the metal layer 115 is the same as that of the circuit pattern 114. The metal layer may be patterned to have the same area as that of the circuit pattern and may be a plate-shaped structure having the same area as that of the circuit pattern. For example, the metal layer may have a fm shape, a box-fm shape or a spiral shape, as shown in FIGS. 12 to 14.

The heat-radiating substrate 100 according to the preferred embodiment of the present invention is manufactured through a manufacturing process as described above.

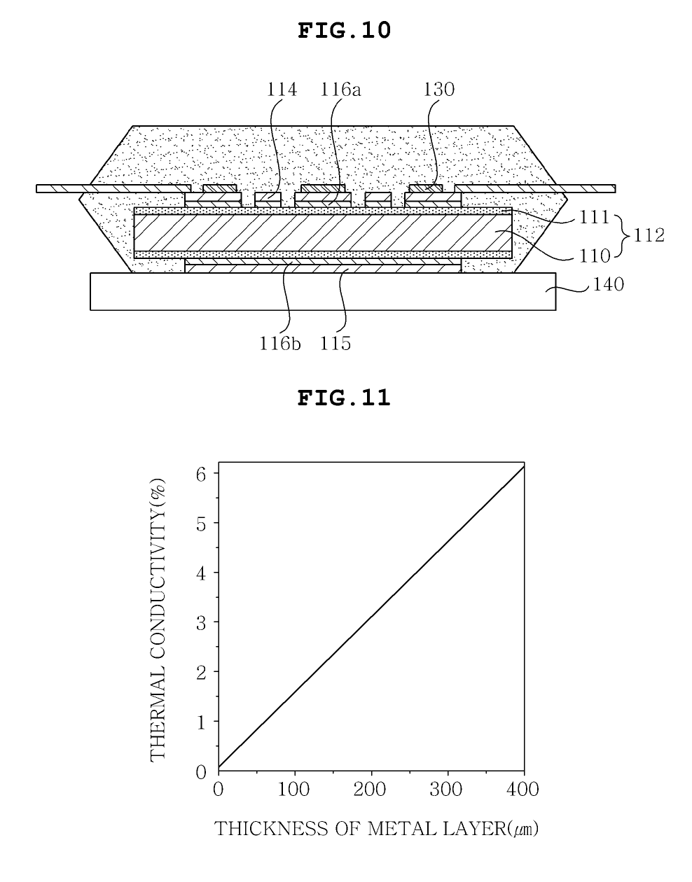

FIGS. 9 and 10 are cross sectional views showing a structure in which a heat-generating element is mounted on the heat-radiating substrate show in FIG. 1.

Specifically, the circuit pattern 114 of the heat-radiating substrate 100 according to the preferred embodiment of the present invention is connected to the heat generating element 130 and the metal layer 115 is connected to the heat-radiating plate 140. Herein, the metal layer 115 formed on the other surface of the anodized substrate 112 (or the second seed layer 116b formed on the other surface of the anodized substrate 112) is in direct contact with the heat radiating plate 140, thereby making it possible to solve a performance deterioration problem of the heat-radiating substrate 100 such as lowering of electrical withstanding voltage, increase of a leakage current, and the like, due to a corner breakage phenomenon of the anodized substrate 112 or a breakage phenomenon of the anodized film 111 generated in a repetitive processing process such as loading, transfer, carrying-out, and the like, of the substrate within a predetermined control environment.

Meanwhile, although a structure of the heat-radiating substrate 100 in which the anodized film 111 is formed over the metal substrate 110 is shown in FIGS. 1 and 8, when the heat-radiating substrate is manufactured in a panel form during a manufacturing process thereof and is cut for each unit substrate, the metal substrate at a side or a corner may be exposed, as shown in FIG. 10. The structure of the heat-radiating substrate 100 shown in FIG. 10 may also be included in the scope of the present invention.

According to the preferred embodiment of the present invention, the metal layer is additionally formed on a lower surface of an existing single-sided anodized substrate, thereby making it possible to improve a warpage problem of the substrate generated due to stress.

According to the preferred embodiment of the present invention, the metal layer added on the lower surface of the anodized substrate is in direct contact with the heat-radiating plate, thereby making it possible to prevent a corner breakage phenomenon generated in a repetitive processing process such as loading, transfer, carrying-out, and the like, of the substrate within a predetermined control environment. Accordingly, it is possible to solve a performance deterioration problem of the heat-radiating substrate and the heat generating element.

According to the preferred embodiment of the present invention, the metal layer (for example, copper layer) having high thermal conductivity is additionally formed, thereby making it possible to improve a heat-radiating performance.

Although the preferred embodiments of the present invention have been disclosed for illustrative purposes, they are for specifically explaining the present invention and thus the heat-radiating substrate and a method for manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A heat-radiating substrate, comprising:
an anodized substrate having an anodized film formed over a metal substrate;
a circuit pattern formed on one surface of the anodized substrate; and
a metal layer formed on the other surface of the anodized substrate.

2. The heat-radiating substrate as set forth in claim 1, further comprising a seed layer between one surface of the anodized substrate and the circuit pattern or between the other side of the anodized substrate and the metal layer.

3. The heat-radiating substrate as set forth in claim 1, wherein the circuit pattern is formed by patterning a plating layer formed on one surface of the anodized substrate.

4. The heat-radiating substrate as set forth in claim 1, wherein the metal layer has the same area as that of the circuit pattern.

5. The heat-radiating substrate as set forth in claim 1, wherein a thickness of the metal layer is 10 μm or more to 1 mm or less.

6. The heat-radiating substrate as set forth in claim 1, wherein the metal layer has a shape in which a plurality of bars are disposed in parallel with each other.

7. The heat-radiating substrate as set forth in claim 1, wherein the metal layer includes:
an outermost metal layer formed in a rectangular shape by connecting four bars at an outermost portion inside an edge of the anodized substrate;
N intermediate metal layers formed in a rectangular shape inside the outermost metal layer and having reduced-size rectangular shapes toward an inner center of the anodized substrate; and
innermost metal layers formed inside the intermediate metal layer formed at an innermost portion of the N intermediate metal layers and having a plurality of bar shapes arranged in parallel with each other.

8. The heat-radiating substrate as set forth in claim 1, wherein the metal layer has a spiral shape.

9. The heat-radiating substrate as set forth in claim 1, wherein the metal layer is formed only within an edge on the other surface of the anodized substrate.

10. The heat-radiating substrate as set forth in claim 1, wherein the metal substrate is made of aluminum and the anodized film is made of alumina.

11. The heat-radiating substrate as set forth in claim 1, wherein the metal layer is made of copper.

12. The heat-radiating substrate as set forth in claim 1, wherein the circuit pattern is connected to a heat generating element and the metal layer is connected to a heat-radiating plate.

13. A method for manufacturing a heat-radiating substrate, comprising:
(A) forming an anodized film over a metal substrate to prepare an anodized substrate;
(B) forming a plating layer on one surface of the anodized substrate and forming a metal layer on the other surface thereof; and
(C) patterning the plating layer to form a circuit pattern.

14. The method for manufacturing a heat-radiating substrate as set forth in claim 13, further comprising, after step (A), (A′) forming a seed layer using an electroless plating process or a sputtering process.

15. The method for manufacturing a heat-radiating substrate as set forth in claim 13, wherein at step (B), the plating layer and the metal layer are simultaneously formed.

16. The method for manufacturing a heat-radiating substrate as set forth in claim 13, further comprising, after step (B), removing an edge of the metal layer so that the metal layer is formed only within an edge on the other surface of the anodized substrate.

17. The method for manufacturing a heat-radiating substrate as set forth in claim 13, further comprising, after step (B), patterning the metal layer so that the metal layer has the same area as that of the circuit pattern.

18. The method for manufacturing a heat-radiating substrate as set forth in claim 13, wherein the metal substrate is made of aluminum and the anodized film is made of alumina.

19. The method for manufacturing a heat-radiating substrate as set forth in claim 13, wherein the metal layer is made of copper.

20. The method for manufacturing a heat-radiating substrate as set forth in claim 13, wherein step (C) includes:
(C1) applying an etching resist on the plating layer;
(C2) patterning the etching resist to form an etching resist pattern; and
(C3) selectively etching the plating layer exposed from the etching resist pattern to form a circuit pattern.
